(19) United States
(12) Patent Application Publication
(10) Pub. No.: US 2010/0294651 A1
(43) Pub. Date: Nov. 25, 2010

(54) PROCESS FOR PRODUCING GRAY TONE MASK

(75) Inventors: Fumihiko Yamada, Chichibu-shi (JP); Toshiharu Ozaki, Chichibu-shi (JP); Takaei Sasaki, Chichibu-shi (JP); Masahiko Ishizuka, Chichibu-shi (JP); Kagehiro Kageyama, Chichibu-shi (JP); Hiroyuki Iso, Chichibu-shi (JP); Ryouichi Kobayashi, Chichibu-shi (JP); Atsushi Hayashi, Chichibu-shi (JP)

Correspondence Address: J. Rodman Steele;Novak Druce & Quigg LLP, 525 Okeechobee Blvd, Suite 1500, West Palm Beach, FL, 33401, US

(73) Assignee: ULVAC COATING CORPORATION, 368-0056 Saitama (JP)

(21) Appl. No.: 12/682,549

(22) PCT Filed: Oct. 9, 2008
(86) PCT No.: PCT/JP2008/068332

§ 371 Date: Apr. 9, 2010

(30) Foreign Application Priority Data
Oct. 12, 2007 (JP) 2007-266959

(51) Int. Cl. C23C 14/34

(52) U.S. Cl. 204/192.26

(57) ABSTRACT

A method for manufacturing a gray-tone mask that decreases the wavelength dependency with respect to an exposure wavelength under stable and simple film formation conditions. A reactive sputtering method that sputters a pure Cr target in an atmosphere of Ar and NO is used to form a Cr nitride film having a single-layer structure. Based on a plurality of different spectral transmittance curves obtained under a plurality of film formation conditions having different NO concentrations, a target concentration (intermediate value) for NO is obtained that sets the transmittance uniformity of the semi-transparent film to 1.0% or less in the range of 365 nm to 436 nm or 4.0% or less in the range of 300 nm to 500 nm. Then, a semi-transparent film is formed by using the NO target concentration.

### TECHNICAL FIELD

The present invention relates to a method for manufacturing a gray-tone mask.

### BACKGROUND ART

In a manufacturing process for a flat panel display, a gray-tone mask is used to reduce manufacturing costs.

A gray-tone mask may express exposure amounts for multiple tones with a single mask. Thus, the number of photolithography steps, which correspond to the number of times masks are switched, is less than when using a photomask that cannot express a halftone level. Such gray-tone masks are widely used in various manufacturing steps in addition to multiple tone exposure processes.

A gray-tone mask includes a light shield portion which shields light, an open portion, which transmits light, and a semi-transparent portion, which partially transmits light. To obtain two different exposure amounts, the open portion forms an exposed portion for a 100% exposure amount, and the light shield portion forms an unexposed portion for a 0% exposure amount. The semi-transparent portion forms a half exposed portion with an exposure amount that is between 0% and 100%. The exposure amount of the semi-transparent portion is determined by the transmittance of a semi-transparent film and is selected from a range of 5% to 70% in accordance with the conditions required for a TFT substrate manufacturing process. The transmittance as referred to in the present invention is the transmittance of light.

In general, gray-tone masks are classified into slit masks and halftone masks in accordance with the structure of a semi-transparent portion. FIG. 22(a) is a plan view and FIG. 22(b) is a cross-sectional view, each showing the structure of a slit mask SOS. FIGS. 23(a) and 23(b) are plan views and FIGS. 24(a) and 24(b) are cross-sectional views, each showing the structure of a halftone mask 50H.

As shown in FIG. 22, the slit mask 50S has a light shield portion 51, a light-transmission portion 52, and a semi-transparent portion 53 on a transparent substrate S. The semi-transparent portion 53 of the slit mask 50S has a slit pattern 53a with a pitch corresponding to the resolution limit on the transparent substrate S. The slit pattern 53a obtains the middle exposure amount. However, when using the slit mask 50S, enlargement of a photomask increases printing data for forming the slit pattern 53a. In a manufacturing process using the slit mask 505, this lengthens the fabrication time of the slit mask 50 and raises production costs. Hence, in the manufacturing process using a gray-tone mask, there is a demand for decreasing the printing data described above.

Known structures for the halftone mask 50H include a structure having a light shield film UF between a transparent substrate S and a semi-transparent film TF as shown in FIGS. 23(a) and 23(b), a structure having a semi-transparent film TF between a transparent substrate S and the light shield film UF as shown in FIGS. 24(a) and 24(b), and a structure having an etching stopper layer between a semi-transparent film TF and a light shield film UF. In the halftone mask 50H, a middle exposure amount is obtained by the optical characteristics of the semi-transparent film. In comparison with the slit mask 50S, this significantly decreases the printing data described above. Thus, the fabrication time of a gray-tone mask is not lengthened and production costs are prevented from increasing.

Exposure light in an exposure process is generally not a single-frequency light. Exposure light includes light having a central wavelength of, for example, an i-line (wavelength of 365 nm), an h-line (wavelength of 405 nm), or a g-line (wavelength of 436 nm) and light having a wavelength near the central wavelength. The energy of exposure light irradiating an exposure subject is the total energy of the wavelengths. Thus, when the transmittance of the semi-transparent is not dependent on the wavelength, high reproducibility is obtained for the exposure result regardless of the selected wavelength. As the semi-transparent film TF used for the halftone mask 50H, chromium oxide film and Cr oxynitride film are known. The transmittance of the Cr oxynitride, as shown in FIG. 25, continuously increases from a short-wavelength region near the wavelength of 300 nm to a long-wavelength region near the wavelength of 700 nm. Thus, with regard to the optical characteristics of a gray-tone mask, it is desirable that the transmittance not be substantially dependent on the wavelength to obtain high exposure reproducibility at different selected wavelengths. A metal film or nitride film of chromium is discussed as a material for the semi-transparent film that decreases the wavelength dependency of the transmittance in, for example, patent documents 1 to 4.

In patent document 1, a semi-transparent film of chromium nitride is formed by performing reactive sputtering using a process gas in which 60 vol % to 100 vol % is nitrogen (N₂) gas and the remnant is argon (Ar). In patent document 1, this obtains a semi-transparent film having the transmittance uniformity of about 5% in the wavelength range of 300 nm to 500 nm.

In patent document 2 and patent document 3, a semi-transparent film that is a metal chromium film is formed by performing reactive sputtering using Ar of 80 vol % and N₂ of 20 vol %. Thus, in patent document 2 and patent document 3, a semi-transparent film having, for example, a transmittance of 37% for the i-line (wavelength of 365 nm) and a transmittance of 35% for the g-line (wavelength of 436 nm) is obtained.

Patent document 4 discusses a semi-transparent film having a two-layer structure of a metal Cr film and an extremely thin Cr oxynitride film. This obtains a semi-transparent film having the transmittance uniformity of about 0.8% in the wavelength range of 300 nm to 500 nm.

In the semi-transparent films described in patent documents 1 to 3, the wavelength dependency of the transmittance is lower than a semi-transparent film formed by a chromium oxide film or a Cr oxynitride film. However, none of the publications specifically describe or sufficiently address a method for manufacturing a semi-transparent film that has substantially no wavelength dependency. In the semi-transparent film of patent document 4, the semi-transparent film employs the two-layer structure. Thus, film formation conditions of the layers must be adjusted to obtain the desired transmittance. Such adjustments of the film formation conditions are burdensome. Hence, such a film lacks versatility.

### Patent Document 1: Japanese Laid-Open Patent Publication No. 2006-268035

### Patent Document 2: Japanese Laid-Open Patent Publication No. 2007-171623

### Patent Document 3: Japanese Laid-Open Patent Publication No. 2007-178649

### Patent Document 4: Japanese Laid-Open Patent Publication No. 2007-133098

### DISCLOSURE OF THE INVENTION

The present invention provides a method for manufacturing a gray-tone mask that decreases wavelength dependency on an exposure wavelength under stable and simple film formation conditions.

One aspect of the present invention is a method for manufacturing a gray-tone mask including a semi-transparent film. The method includes the step of forming the semi-transparent film with a single-layer structure by using a reactive sputtering method that sputters a target formed from a Cr or Ni alloy in an atmosphere of a reactive gas and a sputtering gas. The reactive gas contains at least one selected from the group consisting of oxygen, carbon monoxide, carbon dioxide, nitrogen monoxide, nitrogen dioxide, nitrogen, and methane. The step of forming the semi-transparent film includes acquiring spectral transmittance curves of a plurality of thin films under a plurality of film formation conditions having different concentrations of the reactive gas, acquiring from the spectral transmittance curves of the plurality of thin films a target concentration for the reactive gas that is a concentration at which the difference between a maximum value and a minimum value of a transmittance of the semi-transparent film is 1.0% or less in the wavelength range of 365 nm to 436 nm or 4.0% or less in the wavelength range of 300 nm to 500 nm, and forming the semi-transparent film by using the reactive gas of the target concentration.

### BRIEF DESCRIPTION OF THE DRAWINGS

FIG. 1 is a graph showing the wavelength dependency of the transmittance of a semi-transparent film;

FIG. 2 is a graph showing a spectral transmittance curve of an NO-added Cr semi-transparent film;

FIG. 3 is a graph showing a spectral transmittance curve of an NO-added Cr semi-transparent film;

FIG. 4 is a graph showing a spectral transmittance curve of an N₂-added Cr semi-transparent film;

FIG. 5 is a graph showing a spectral transmittance curve of an N₂-added Cr semi-transparent film;

FIG. 6 is a graph showing a spectral transmittance curve of an N₂-added NiCr semi-transparent film;

FIG. 7 is a graph showing a spectral transmittance curve of an N₂-added NiCr semi-transparent film;

FIG. 8 is a graph showing a spectral transmittance curve of a CO₂-added Cr semi-transparent film;

FIG. 9 is a graph showing a spectral transmittance curve of a CO₂-added Cr semi-transparent film;

FIG. 10 is a graph showing the transmittance uniformity of an NO-added Cr semi-transparent film;

FIG. 11 is a graph showing the transmittance uniformity of an NO-added Cr semi-transparent film;

FIG. 12 is a graph showing an NO concentration in an NO-added Cr semi-transparent film;

FIG. 13 is a graph showing the transmittance uniformity of an N₂-added Cr semi-transparent film;

FIG. 14 is a graph showing the transmittance uniformity of an N₂-added Cr semi-transparent film;

FIG. 15 is a graph showing the N₂ concentration of an N₂-added Cr semi-transparent film;

FIG. 16 is a graph showing the transmittance uniformity of an N₂-added NiCr semi-transparent film;

FIG. 17 is a graph showing the transmittance uniformity of an N₂-added NiCr semi-transparent film;

FIG. 18 is a graph showing the N₂ concentration of an N₂-added NiCr semi-transparent film;

FIG. 19 is a graph showing the transmittance uniformity of a CO₂-added Cr semi-transparent film;

FIG. 20 is a graph showing the transmittance uniformity of a CO₂-added Cr semi-transparent film;

FIG. 21 is a graph showing the CO₂ concentration of a CO₂-added Cr semi-transparent film;

FIG. 22(a) is a plan view and FIG. 22(b) is a cross-sectional view, each showing a gray-tone mask of the prior art;

FIG. 23(a) is a plan view and FIG. 23(b) is a cross-sectional view, each showing a gray-tone mask of the prior art; and

FIG. 24(a) is a plan view and FIG. 24(b) is a cross-sectional view, each showing a gray-tone mask of the prior art; and

FIG. 25 is a graph showing the wavelength dependency of the transmittance of the prior art semi-transparent film.

### DESCRIPTION OF REFERENCE NUMERALS

50H . . . gray-tone mask, 51 . . . light shield portion, 52 . . . open portion, 53 . . . semi-transparent portion

### BEST MODE FOR CARRYING OUT THE INVENTION

A two-layer thin film (hereinafter simply referred to as a laminated film) generally has optical characteristics obtained by combining the optical characteristics of each layer, with the effective transmittance being an intermediate value of the transmittance of each layer. In such a laminated film, the spectral transmittance for each layer is selected as required to obtain the desired spectral transmittance characteristics.

For example, when the spectral transmittance curve for each layer of the laminated film is in line symmetry about a wavelength axis extending through a predetermined transmittance, the wavelength dependencies of the layers offset each other. Thus, the spectral transmittance of the laminated film is substantially not wavelength dependent. On the other hand, when the spectral transmittance curve for each layer is not in line symmetry about the wavelength axis, the wavelength dependency of each layer may be reflected as a wavelength dependency in a spectral transmittance of the laminated film.

In a single-layer thin film, the composition ratio of the materials forming the thin film is equal to an intermediate value of the composition ratio of the layers forming the laminated film. This obtains the same optical characteristics as that of the laminated film. For example, when the layers of the laminated film are formed by performing reactive sputtering and the film formation conditions for each layer differs only in flow rate of the reactive gas, the same optical characteristics as the laminated film may be obtained by the single-layer film as long as the single-layer film is formed using an intermediate value of the flow rate for each layer.

The inventors of the present invention have conducted experiments and have confirmed that when performing reactive sputtering using Cr or an Ni alloy as a target, a thin film in which oxidation, oxynitridation, nitridation, and carbonization have sufficiently progressed has transmittance that is greatly wavelength dependent. The present inventors have learned that a spectral transmittance curve in a metal compound film in which oxidation, oxynitridation, nitridation, and carbonization have sufficiently progressed and a spectral transmittance curve of a metal film formed from metal have substantial line symmetry about a wavelength axis.

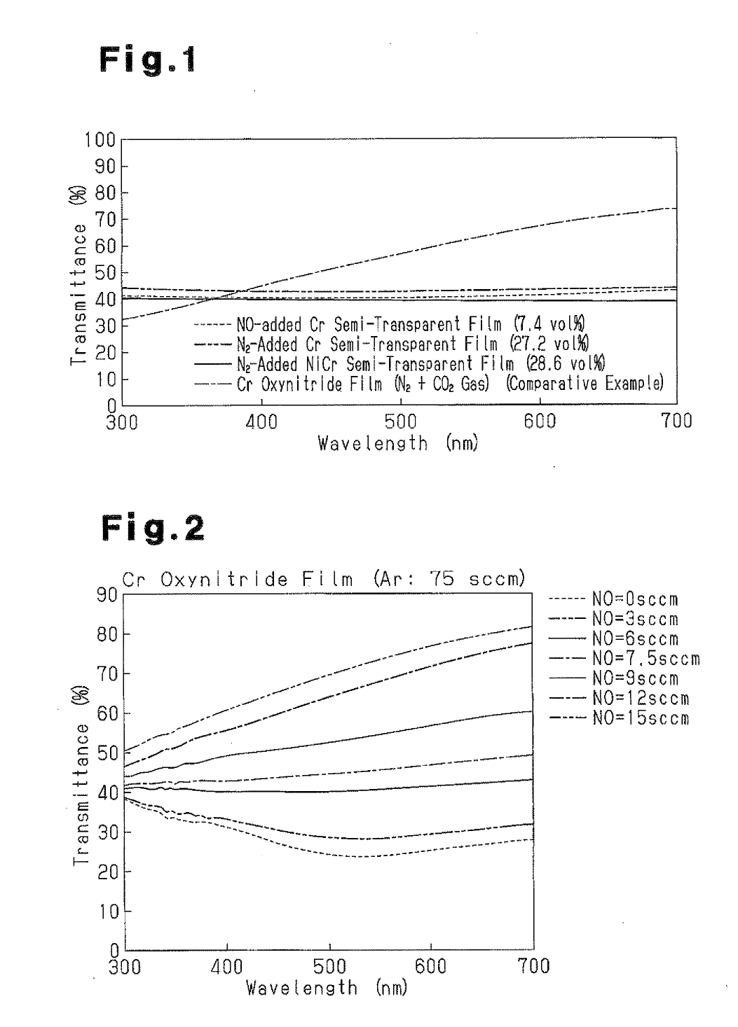

A method for manufacturing a gray-tone mask according to one embodiment of the present invention will now be discussed with reference to the drawings. FIG. 1 is a graph showing the wavelength dependency of the transmittance of a semi-transparent film formed by performing reactive sputtering.

In FIG. 1, the “NO-added Cr semi-transparent film” (broken line) indicates the spectral transmittance curve of a semi-transparent film formed by using a pure Cr target as a sputtering target, a nitrogen monoxide (NO) gas of 7.4 vol % as a reactive gas, and an argon (Ar) gas of 92.6 vol % as a sputtering gas.

The “N₂-added Cr semi-transparent film” (double-dashed line) indicates the spectral transmittance curve of a semi-transparent film formed by using a pure Cr target as a sputtering target, an N₂ gas of 27.2 vol % as a reactive gas, and an Ar gas of 72.8 vol % as a sputtering gas.

The “N₂-added NiCr semi-transparent film” (solid line) indicates the spectral transmittance curve of a semi-transparent film formed by using an NiCr target as a sputtering target, an N₂ gas of 28.6 vol % as a reactive gas, and an Ar gas of 71.4 vol % as a sputtering gas.

In FIG. 1, the “NO-added Cr semi-transparent film”, the “N₂-added Cr semi-transparent film”, and the “N₂-added NiCr semi-transparent film” each have a transmittance uniformity of 1.0% or less in the wavelength range of 365 nm to 436 nm or a transmittance uniformity of 4.0% or less in the wavelength range of 300 nm to 500 nm and thus substantially does not have wavelength dependency.

In addition to a Cr oxynitride film serving as the NO-added Cr semi-transparent film, a Cr nitride film serving as the N₂-added Cr semi-transparent film, and an NiCr nitride film serving as the N₂-added Cr semi-transparent film, a chromium oxycarbide film serving as the CO₂-added Cr semi-transparent film will now be discussed using examples.

### Example 1

### Cr Oxynitride Film

A target having a thickness of 6 mm and formed from pure Cr was used as a sputtering target, a silica substrate having a thickness of 5.0 mm was used as a substrate, and a large interback type film formation apparatus was used. Conditions that were set included the film formation temperature, which is the substrate temperature for film formation, the sputtering gas, the reactive gas, the film formation pressure, which is the pressure for film formation, and the target electric power, which is the power input to the target. The conditions were set as described below to obtain a semi-transparent film, which is a Cr oxynitride film, in example 1. In this case, the conveying speed of a substrate passing through a film formation area was controlled to maintain the film quality of the film throughout the substrate, and the film thickness of the Cr oxynitride film was adjusted to 5 nm to 20 nm, which is the film thickness when the transmittance is 30% to 50% in a semi-transparent film having a transmittance that is substantially not wavelength dependent.

Film formation temperature: 150° C. to 200° C.
Sputtering gas/sputtering gas flow rate: Ar/35 sccm to 75 sccm
Reactive gas/reactive gas flow rate: nitrogen monoxide (NO)/0 sccm to 15 sccm
Film formation pressure: 1.1×10⁻¹ Pa to 6.4×10⁻¹ Pa
Target electric power: approximately 2.5 kW (power density: 0.9 W/cm²)

The spectral transmittance for each Cr oxynitride film in example 1 was measured. Further, the difference between the maximum transmittance and the minimum transmittance in the wavelength range of 365 nm to 436 nm and the difference between the maximum transmittance and the minimum transmittance in the wavelength range of 300 nm to 500 nm were each calculated as the transmittance uniformity.

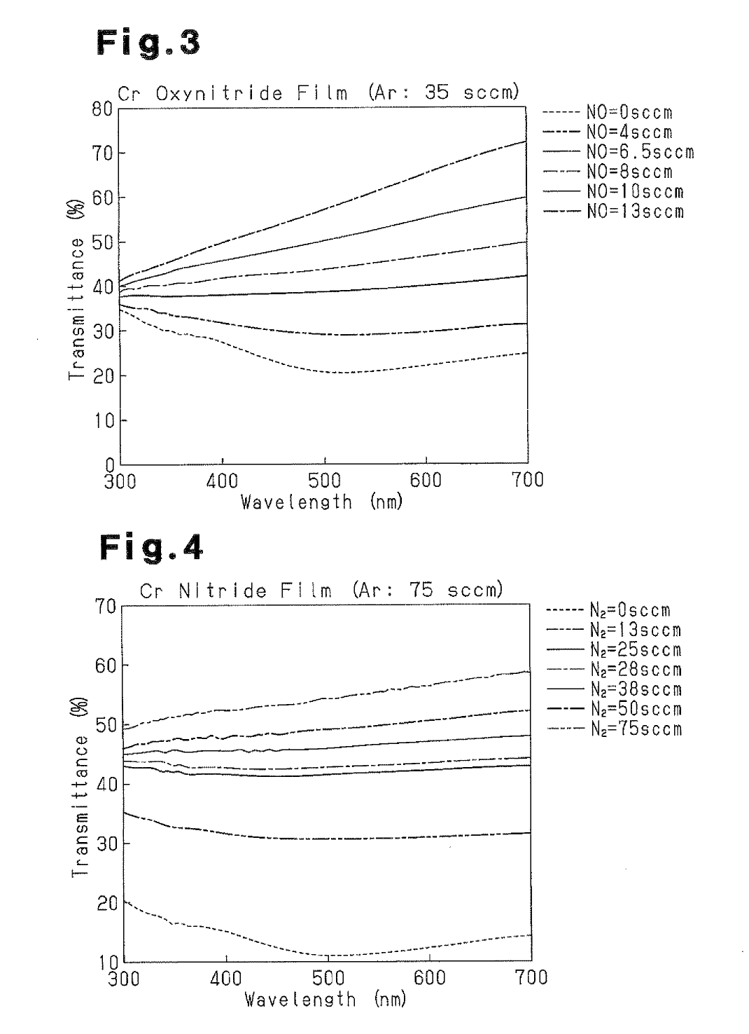

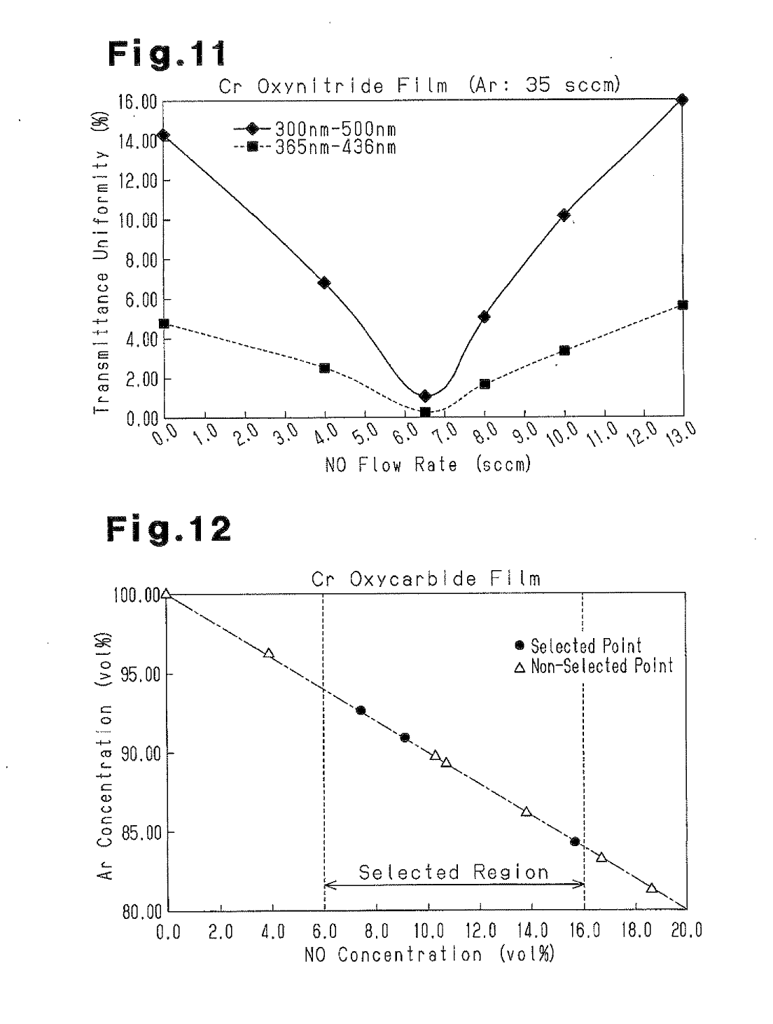

FIG. 2 shows the spectral transmittance curve of a Cr oxynitride film formed under an Ar flow rate of 75 sccm, the condition of which is included in the above conditions. FIG. 3 shows the spectral transmittance curve of a Cr oxynitride film formed under an Ar flow rate of 35 sccm, the condition of which is included in the above conditions. Further, FIG. 10 and Table 1 show the transmittance uniformity of the Cr oxynitride film formed under the condition in which the Ar flow rate is 75 sccm. FIG. 11 and Table 2 show the transmittance uniformity of the Cr oxynitride film formed under the condition in which the Ar flow rate is 35 sccm. FIG. 12 and Table 3 show a region (hereinafter simply referred to as a selected region) having an NO concentration at which the transmittance uniformity in the wavelength range of 365 nm to 436 nm may be 1.0% or less or the transmittance uniformity in the wavelength range of 300 nm to 500 nm may be 4.0% or less.

As shown in FIG. 2, when the Ar flow rate is 75 ccm, in a film formed under the condition in which the NO flow rate is 0 sccm, as the measured wavelength increases from 300 nm to 500 nm, the transmittance of the film gradually decreases from about 40%. When the NO flow rate gradually increases from 0 sccm, in the transmittance curve of the Cr oxynitride film, a decreasing tendency of the transmittance becomes gradual. In a Cr oxynitride film formed under the condition in which the NO flow rate is 12 sccm, the transmittance gradually increases from about 40%.

The spectral transmittance curve of a film formed under the condition in which the NO flow rate is 0 sccm and the spectral transmittance curve of a Cr oxynitride film formed under the condition that oxynitridation has sufficiently progressed are substantially in line symmetry about a wavelength axis. More specifically, it is apparent that the spectral transmittance curve of a film obtained under the condition in which the NO flow rate is 0 sccm and the spectral transmittance curve of a Cr oxynitride film formed under the condition in which the NO flow rate is 12 sccm are substantially in line symmetry about a wavelength axis extending through the transmittance of about 40%. It is also apparent that the transmittance curve of the Cr oxynitride film at 6 sccm, which is an intermediate value of the two NO flow rates that have line symmetrical spectral transmittances, is substantially parallel to a wavelength axis in the wavelength range of 300 nm to 500 nm.

The NO flow rate dependency of the spectral transmittance may also be confirmed from FIG. 3. More specifically, when the Ar flow rate is 35 ccm, it is apparent that the spectral transmittance curve of a Cr film formed under the condition in which the NO flow rate is 0 sccm and the spectral transmittance curve of a Cr film formed under the condition in which the NO flow rate is 13 sccm are substantially in line symmetry about a wavelength axis extending through the transmittance of about 40%. It is apparent that the transmittance curve of the Cr oxynitride film at 6.5 sccm, which is an intermediate value of the two NO flow rates that have line symmetrical spectral transmittances, is substantially parallel to a wavelength axis in the wavelength range of 300 nm to 500 nm.

As shown in FIG. 10, under the condition in which the Ar flow rate is 75 ccm, the transmittance uniformity of the Cr oxynitride film at 6 sccm, which is an intermediate value, is 0.45% in the wavelength range of 365 nm to 436 nm and 1.08% in the wavelength range of 300 nm to 500 nm. The transmittance uniformity of the Cr oxynitride film decreases as the NO flow rate approaches the intermediate value from 0 sccm. In a region including the intermediate value of 6 sccm, the transmittance uniformity is 1.0% or less in the wavelength range of 365 nm to 436 nm or 4.0% or less in the wavelength range of 300 nm to 500 nm. The transmission uniformity increases as the NO flow rate increases from the intermediate value. Thus, under the condition in which the Ar flow rate is 75 ccm, in a film formation process for the Cr oxynitride film, when the intermediate value is set to a target flow rate, which is a target concentration, the transmittance uniformity is further stabilized with respect to the NO flow rate.

The NO flow rate dependency of the transmittance uniformity may also be confirmed from FIG. 11. More specifically, under the condition in which the Ar flow rate is 35 sccm, when the intermediate value is 6.5 sccm, the transmittance uniformity of a Cr oxynitride film is 0.31% in the wavelength range of 365 nm to 436 nm and 1.18% in the wavelength range of 300 nm to 500 nm. The transmittance uniformity of the Cr oxynitride film decreases as the NO flow rate approaches the intermediate value from 0 sccm, enters a state in which it is substantially not wavelength dependent in a region including 6.5 sccm, which is the intermediate value, and increases as the NO flow rate increases from the intermediate value. Thus, when the Ar flow rate is 35 ccm, in the film formation process of the Cr oxynitride film, by using the intermediate value of 6.5 sccm which as a target flow rate, the transmittance uniformity is further stabilized with respect to the NO flow rate.

In FIG. 12, the volume percentages of the gaseous species obtained from an NO flow rate and an Ar flow rate are respectively referred to as an NO concentration and an Ar concentration. In the above-described film formation conditions, a point at which the transmittance uniformity in the wavelength range of 365 nm to 436 nm is 1.0% or less or the transmittance uniformity in the wavelength range of 300 nm to 500 nm is 4.0% or less is referred to as a selected point. A point at which the transmittance uniformity in the wavelength range of 365 nm to 436 nm is greater than 1.0% and the transmittance uniformity in the wavelength range of 300 nm to 500 nm is greater than 4.0% is referred to as a non-selected point.

As shown in FIG. 12, in a region in which the NO concentration is 6% to 16% and the remnant is formed of Ar, namely, in the region of the selected region of the NO concentration shown in FIG. 12 lying along the single-dashed line, a large number of selected points may be recognized. This is because the Cr oxynitride film substantially does not have wavelength dependency at the intermediate value, and such characteristics are easily obtained near the intermediate value. Accordingly, in a film formation process for the Cr oxynitride film that performs reactive sputtering with a pure Cr target, it is understood that a Cr oxynitride film that substantially does not have wavelength dependency is easily obtained by selecting the NO concentration from the region in which the NO concentration is 6% to 16%.

### Example 2

### Cr Nitride Film

A target having a thickness of 6 mm and formed from pure Cr was used as a sputtering target, a silica substrate having a thickness of 5.0 mm was used as a substrate, and a large interback type film formation apparatus was used in the same manner as in example 1. The film formation temperature, sputtering gas, reactive gas, film formation pressure, and target electric power were set under the conditions shown below to obtain the semi-transparent film of example 2 formed by a Cr nitride film. In this case, the film thickness of the Cr nitride film, which was controlled by the conveying speed of the substrate passing through the film formation area to maintain the film quality of the film throughout the substrate, was adjusted to 5 nm to 20 nm, which is the film thickness when the transmittance is 30% to 50% in a semi-transparent film having a transmittance that is substantially not wavelength dependent.

Film formation temperature: 150° C. to 200° C.
Sputtering gas/sputtering gas flow rate: Ar/35 sccm to 75 sccm
Reactive gas/reactive gas flow rate: nitrogen (N₂)/0 sccm to 80 sccm
Film formation pressure: 1.3×10⁻¹ Pa to 5.7×10⁻¹ Pa
Target electric power: approximately 2.5 kW (power density: 0.9 W/cm²)

The spectral transmittance for each Cr nitride film in example 2 was measured. Further, the difference between the maximum transmittance and the minimum transmittance in the wavelength range of 365 nm to 436 nm and the difference between the maximum transmittance and the minimum transmittance in the wavelength range of 300 nm to 500 nm were each calculated as the transmittance uniformity.

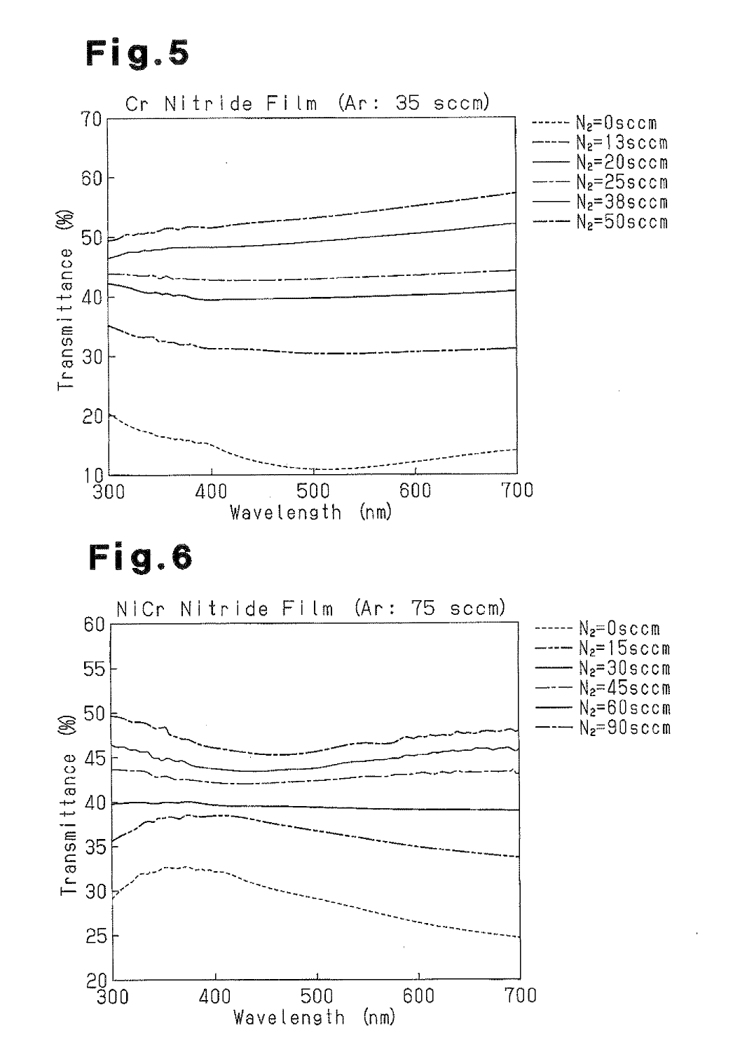

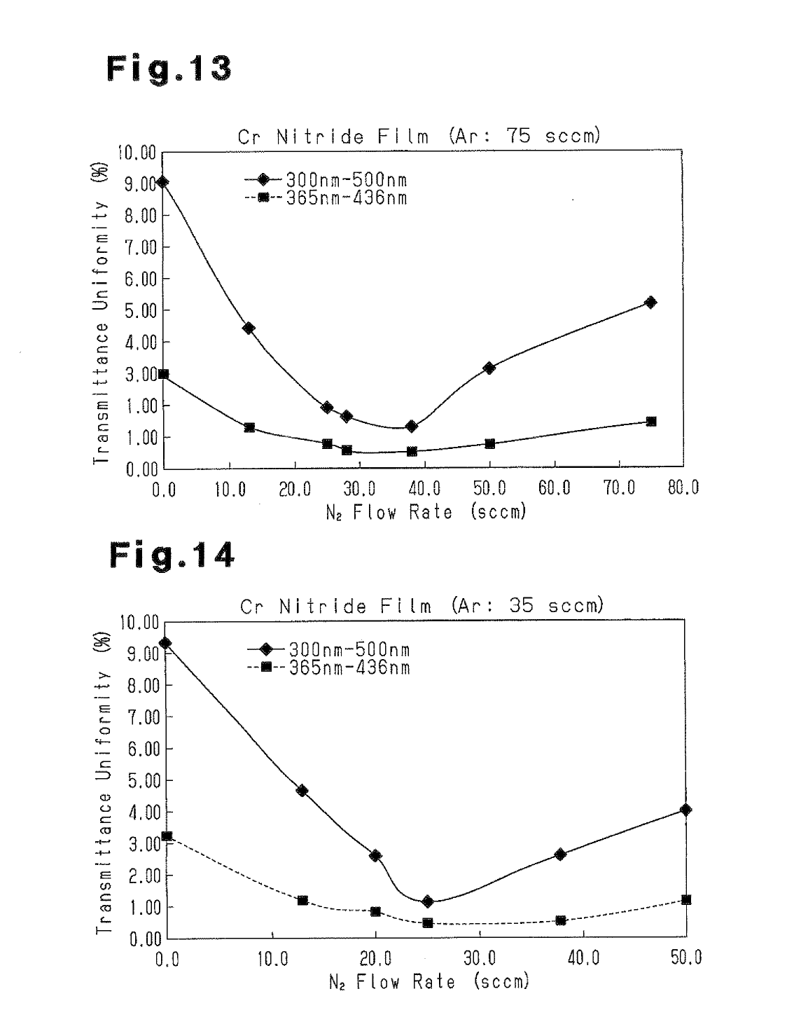

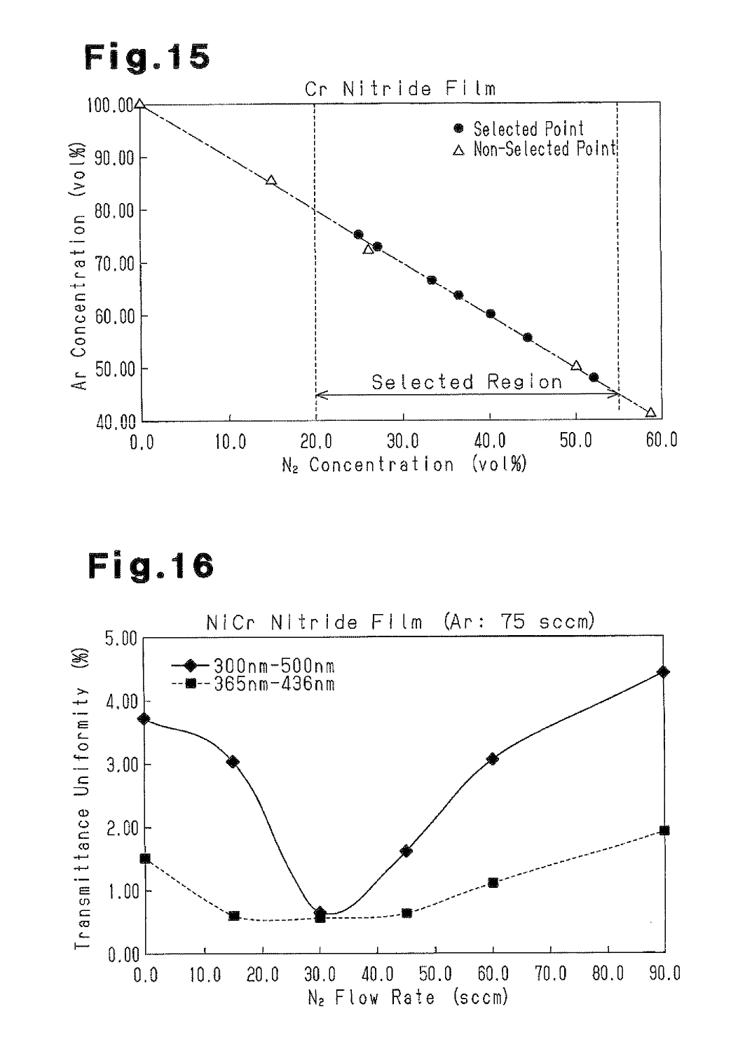

FIG. 4 shows the spectral transmittance curve of a Cr nitride film formed under an Ar flow rate of 75 sccm, the condition of which is included in the above conditions. FIG. 5 shows the spectral transmittance curve of a Cr nitride film formed under an Ar flow rate of 35 sccm, the condition of which is included in the above conditions. Further, FIG. 13 and Table 4 show the transmittance uniformity of the Cr nitride film formed under the condition in which the Ar flow rate is 75 sccm. FIG. 14 and Table 5 show the transmittance uniformity of the Cr nitride film formed under the condition in which the Ar flow rate is 35 sccm. FIG. 15 and Table 6 show a selected region having an N₂ concentration at which the transmittance uniformity in the wavelength range of 365 nm to 436 nm is 1.0% or less or the transmittance uniformity in the wavelength range of 300 nm to 500 nm is 4.0% or less.

As shown in FIG. 4, when the Ar flow rate is 75 sccm, in a film formed under the condition in which the N₂ flow rate is 0 sccm, as the measured wavelength increases from 300 nm to 500 nm, the transmittance of the film gradually decreases. When the N₂ flow rate gradually increases from 0 sccm, in the transmittance curve of the Cr nitride film, a decreasing tendency of the transmittance becomes gradual.

The spectral transmittance curve of a film formed under the condition in which the N₂ flow rate is 0 sccm and the spectral transmittance curve of a Cr nitride film formed under the condition that nitridation has sufficiently progressed are substantially in line symmetry about a wavelength axis. More specifically, it is apparent that the spectral transmittance curve of a film obtained under the condition in which the N₂ flow rate is 75 sccm and the spectral transmittance curve of a Cr nitride film formed under the condition in which the N₂ flow rate is 0 sccm are substantially in line symmetry about a wavelength axis. It is also apparent that the transmittance curve of the Cr nitride film near 38 sccm, which is an intermediate value of the two N₂ flow rates that have line symmetrical spectral transmittances, is substantially parallel to a wavelength axis when the wavelength is in the range of 300 nm to 500 nm. The N₂ flow rate dependency of the spectral transmittance may also be confirmed from FIG. 5.

As shown in FIG. 13, under the condition in which the Ar flow rate is 75 sccm, the transmittance uniformity of the Cr nitride film near 38 sccm, which is the intermediate value, is 1.0% or less in the wavelength range of 365 nm to 436 nm and 4.0% or less in the wavelength range of 300 nm to 500 nm. The transmittance uniformity of the Cr nitride film decreases as the N₂ flow rate approaches the intermediate value from 0 sccm and increases as the N₂ flow rate increases from the intermediate value. Thus, under the condition in which the Ar flow rate is 75 sccm, in a film formation process for the Cr nitride film, when the intermediate value is set to a target flow rate, which is a target concentration, the transmittance uniformity is further stabilized with respect to the N₂ flow rate. The N₂ flow rate dependency of the transmittance uniformity may also be confirmed from FIG. 14.

In FIG. 15, the volume percentages of the gaseous species obtained from an N₂ flow rate and an Ar flow rate are respectively referred to as an N₂ concentration and an Ar concentration. In the above-described film formation conditions, a point at which the transmittance uniformity in the wavelength range of 365 nm to 436 nm is 1.0% or less or the transmittance uniformity in the wavelength range of 300 nm to 500 nm is 4.0% or less is referred to as a selected point. A point at which the transmittance uniformity in the wavelength range of 365 nm to 436 nm is greater than 1.0% and the transmittance uniformity in the wavelength range of 300 nm to 500 nm is greater than 4.0% is referred to as a non-selected point.

As shown in FIG. 15, in a region in which the N₂ concentration is 20% to 55% and the remnant is formed of Ar, namely, in the region of the selected region of the N₂ concentration shown in FIG. 15 lying along the single-dashed line, a large number of selected points may be recognized. This is because there is substantially no wavelength dependency at the intermediate value, and such characteristics are easily obtained near the intermediate value. Accordingly, in a film formation process for the Cr nitride film that performs reactive sputtering with a pure Cr target, it is apparent that a Cr nitride film that substantially does not have wavelength dependency is easily obtained by selecting the N₂ concentration from the region in which the N₂ concentration is 20% to 55%.

### Example 3

### NiCr Nitride Film

A target having a thickness of 6 mm and formed from 92 atomic percent of Ni and 8 atomic percent of Cr was used as a sputtering target, a silica substrate having a thickness of 5.0 mm was used as a substrate, and a large interback type film formation apparatus was used in the same manner as in example 1. The film formation temperature, sputtering gas, reactive gas, film formation pressure, and target electric power were set under the conditions shown below to obtain the semi-transparent film of example 3 formed by a NiCr nitride film. In this case, the film thickness of the NiCr nitride film, which was controlled by the conveying speed of the substrate passing through the film formation area to maintain the film quality of the film throughout the substrate, was adjusted to 5 nm to 20 nm, which is the film thickness when the transmittance is 30% to 50% in a semi-transparent film having a transmittance that is substantially not wavelength dependent.

Film formation temperature: 150° C. to 200° C.
Sputtering gas/sputtering gas flow rate: Ar/35 sccm to 75 sccm
Reactive gas/reactive gas flow rate: nitrogen (N₂)/0 sccm to 90 sccm
Film formation pressure: 2.2×10⁻¹ Pa to 6.4×10⁻¹ Pa
Target electric power: approximately 2.5 kW (power density: 0.9 W/cm²)

The spectral transmittance for each NiCr nitride film in example 3 was measured. Further, the difference between the maximum transmittance and the minimum transmittance in the wavelength range of 365 nm to 436 nm and the difference between the maximum transmittance and the minimum transmittance in the wavelength range of 300 nm to 500 nm were each calculated as the transmittance uniformity.

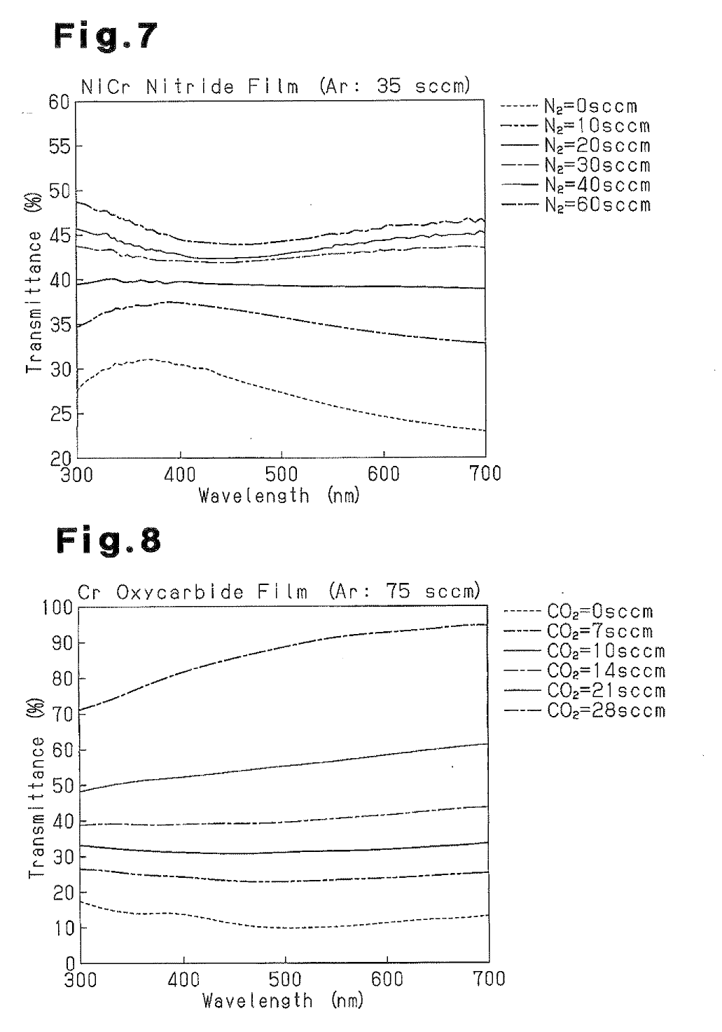

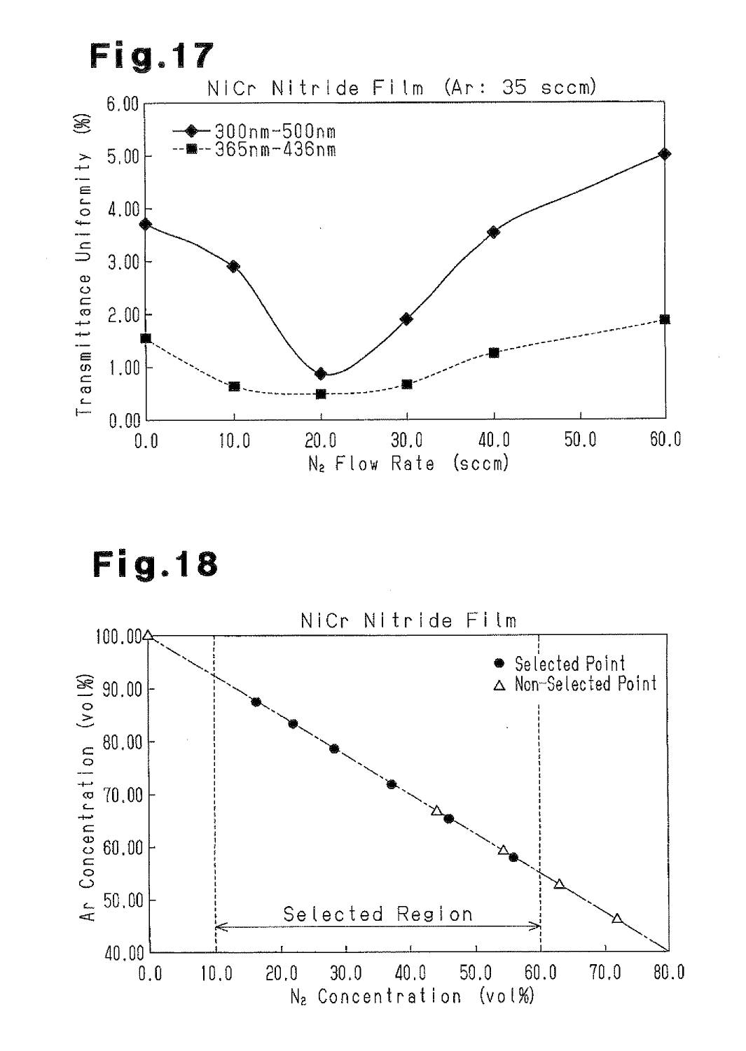

FIG. 6 shows the spectral transmittance curve of a NiCr nitride film formed under an Ar flow rate of 75 sccm, the condition of which is included in the above conditions. FIG. 7 shows the spectral transmittance curve of a NiCr nitride film formed under an Ar flow rate of 35 sccm, the condition of which is included in the above conditions. Further, FIG. 16 and Table 7 show the transmittance uniformity of the NiCr nitride film formed under the condition in which the Ar flow rate is 75 sccm. FIG. 17 and Table 8 show the transmittance uniformity of the NiCr nitride film formed under the condition in which the Ar flow rate is 35 sccm. FIG. 18 and Table 9 show a selected region having an N₂ concentration at which the transmittance uniformity in the wavelength range of 365 nm to 436 nm is 1.0% or less or the transmittance uniformity in the wavelength range of 300 nm to 500 nm is 4.0% or less.

As shown in FIG. 8, when the Ar flow rate is 75 sccm, in a film formed under the condition in which the CO₂ flow rate is 0 sccm has a convex-shaped transmittance curve that projects to a high-transmittance side when the measured wavelength is in the range of 300 nm to 500 nm. When the N₂ flow rate gradually increases from 0 sccm, the convex shape in the transmittance curve of the NiCr nitride film gradually becomes small. In the NiCr nitride film formed at an N₂ flow rate of 60 sccm, the transmittance curve is concave-shaped and recessed to a low-transmittance side.

The spectral transmittance curve of a film formed under the condition in which the N₂ flow rate is 0 sccm and the spectral transmittance curve of a NiCr nitride film formed under the condition that nitridation has sufficiently progressed are substantially in line symmetry about a wavelength axis. More specifically, it is apparent that the spectral transmittance curve of a film obtained under the condition in which the N₂ flow rate is 0 sccm and the spectral transmittance curve of a NiCr nitride film formed under the condition in which the N₂ flow rate is 60 sccm are substantially in line symmetry about a wavelength axis. It is also apparent that the transmittance curve of the NiCr nitride film near 30 sccm, which is an intermediate value of the two N₂ flow rates that have line symmetrical spectral transmittances, is substantially parallel to a wavelength axis when the wavelength is in the range of 300 nm to 500 nm.

The N₂ flow rate dependency of the spectral transmittance may also be confirmed from FIG. 7. More specifically, it is apparent that when the Ar flow rate is 35 ccm, the spectral transmittance curve of a NiCr film formed under the condition that the Ar flow rate is 35 ccm and the spectral transmittance curve of an NiCr nitride film formed under the condition in which the N₂ flow rate is 40 sccm are substantially in line symmetry about the wavelength axis. Further, it is apparent that at 20 sccm, which is the intermediate value of the two N₂ flow rates that obtain axis symmetrical spectral transmittance, the transmittance curve of the NiCr nitride film is substantially parallel to the wavelength axis in the wavelength range of 300 nm to 500 nm.

As shown in FIG. 16, under the condition in which the Ar flow rate is 75 sccm, the transmittance uniformity of the NiCr nitride film near 30 sccm, which is the intermediate value, is 0.54% in the wavelength range of 365 nm to 436 nm and 0.66% in the wavelength range of 300 nm to 500 nm. The transmittance uniformity of the NiCr nitride film decreases as the N₂ flow rate approaches the intermediate value from 0 sccm. Further, the transmittance uniformity of the NiCr nitride film in the region including 30 sccm, which is the intermediate value, is 1.0% or less in the range in which the wavelength is 365 nm to 436 nm and 4.0% or less in the range in which the wavelength is 300 nm to 500 nm. Moreover, the transmittance uniformity increases as the N₂ flow rate increases from the intermediate value. Thus, under the condition in which the Ar flow rate is 75 sccm, in a film formation process for the NiCr nitride film, when the intermediate value is set to a target flow rate, which is a target concentration, the transmittance uniformity is further stabilized with respect to the N₂ flow rate.

The N₂ flow rate dependency of the transmittance uniformity may also be confirmed from FIG. 17. More specifically, under the condition in which the Ar flow rate is 35 sccm, the transmittance uniformity of the NiCr film at 20 sccm, which is the intermediate value, is 0.49% in the wavelength range of 365 nm to 436 nm and 0.88% in the wavelength range of 300 nm to 500 nm. The transmittance uniformity of the NiCr nitride film decreases as the N₂ flow rate approaches the intermediate value from 0 sccm. Further, the transmittance uniformity of the NiCr nitride film, the transmittance uniformity enters a state in which it is substantially not wavelength dependent in a region including 20 sccm, which is the intermediate value, and increases as the N₂ flow rate increases from the intermediate value. Thus, when the Ar flow rate is 35 ccm, in the film formation process of the Cr oxynitride film, by using the intermediate value as a target flow rate, which is the target concentration, the transmittance uniformity is further stabilized with respect to the N₂ flow rate.

In FIG. 18, the volume percentages of the gaseous species obtained from an N₂ flow rate and an Ar flow rate are respectively referred to as an N₂ concentration and an Ar concentration. In the above-described film formation conditions, a point at which the transmittance uniformity in the wavelength range of 365 nm to 436 nm is 1.0% or less or the transmittance uniformity in the wavelength range of 300 nm to 500 nm is 4.0% or less is referred to as a selected point. A point at which the transmittance uniformity in the wavelength range of 365 nm to 436 nm is greater than 1.0% and the transmittance uniformity in the wavelength range of 300 nm to 500 nm is greater than 4.0% is referred to as a non-selected point.

As shown in FIG. 18, in a region in which the N₂ concentration is 10% to 60% and the remnant is formed of Ar, namely, in the region of the selected region of the N₂ concentration shown in FIG. 18 lying along the single-dashed line, a large number of selected points may be recognized. This is because there is substantially no wavelength dependency at the intermediate value, and such characteristics are easily obtained near the intermediate value. Accordingly, when reactive sputtering is performed with an NiCr target, it is apparent that a Cr nitride film that substantially does not have wavelength dependency is easily obtained by selecting the N₂ concentration from the region in which the N₂ concentration is 10% to 60%.

### Example 4

### Cr Oxycarbide Film

A target having a thickness of 6 mm and formed from pure Cr was used as a sputtering target, a silica substrate having a thickness of 5.0 mm was used as a substrate, and a large interback type film formation apparatus was used in the same manner as in Example 1. The film formation temperature, sputtering gas, reactive gas, film formation pressure, and target electric power were set under the conditions shown below to obtain the semi-transparent film of example 4 formed by a Cr oxycarbide film. In this case, the film thickness of the Cr oxycarbide film, which was controlled by the conveying speed of the substrate passing through the film formation area to maintain the film quality of the film throughout the substrate, was adjusted to 5 nm to 20 nm, which is the film thickness when the transmittance is 30% to 50% in a semi-transparent film having a transmittance that is substantially not wavelength dependent.

Film formation temperature: 150° C. to 200° C.
Sputtering gas/sputtering gas flow rate: Ar/35 sccm to 75 sccm
Reactive gas/reactive gas flow rate: carbon dioxide (CO₂)/0 sccm to 30 sccm
Film formation pressure: 2.7×10⁻¹ Pa to 6.0×10⁻¹ Pa
Target electric power: approximately 5.0 kW (power density: 1.8 W/cm²)

The spectral transmittance for each Cr oxycarbide film in example 4 was measured. Further, the difference between the maximum transmittance and the minimum transmittance in the wavelength range of 365 nm to 436 nm and the difference between the maximum transmittance and the minimum transmittance in the wavelength range of 300 nm to 500 nm were each calculated as the transmittance uniformity.

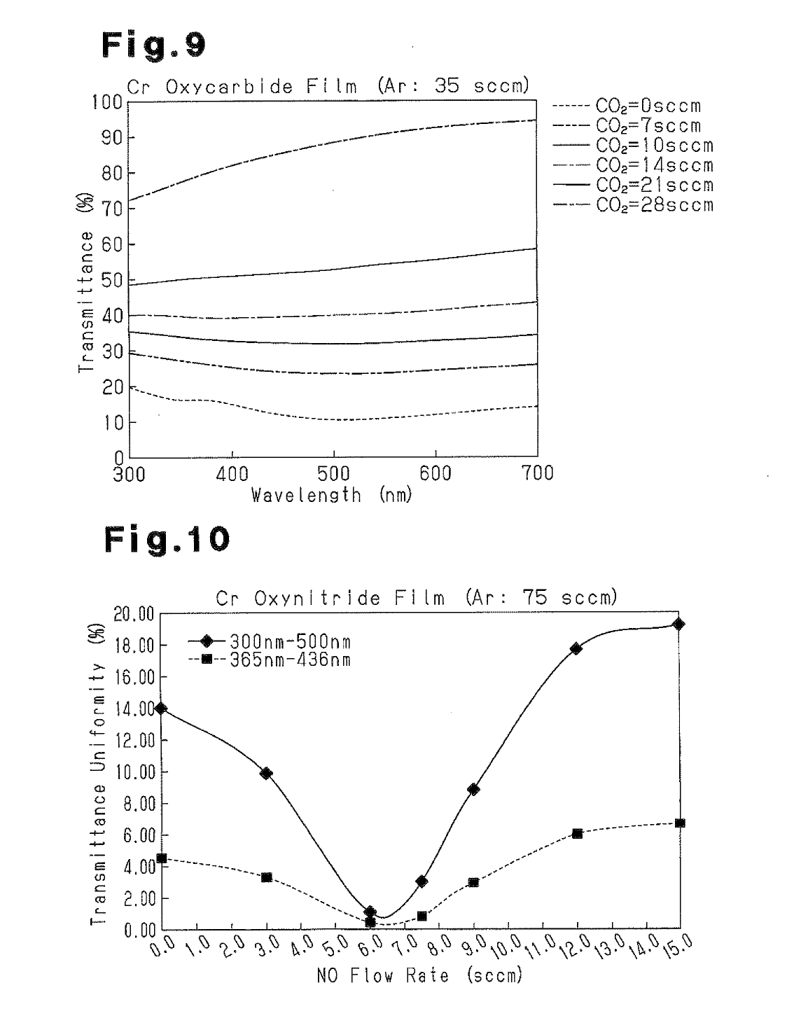

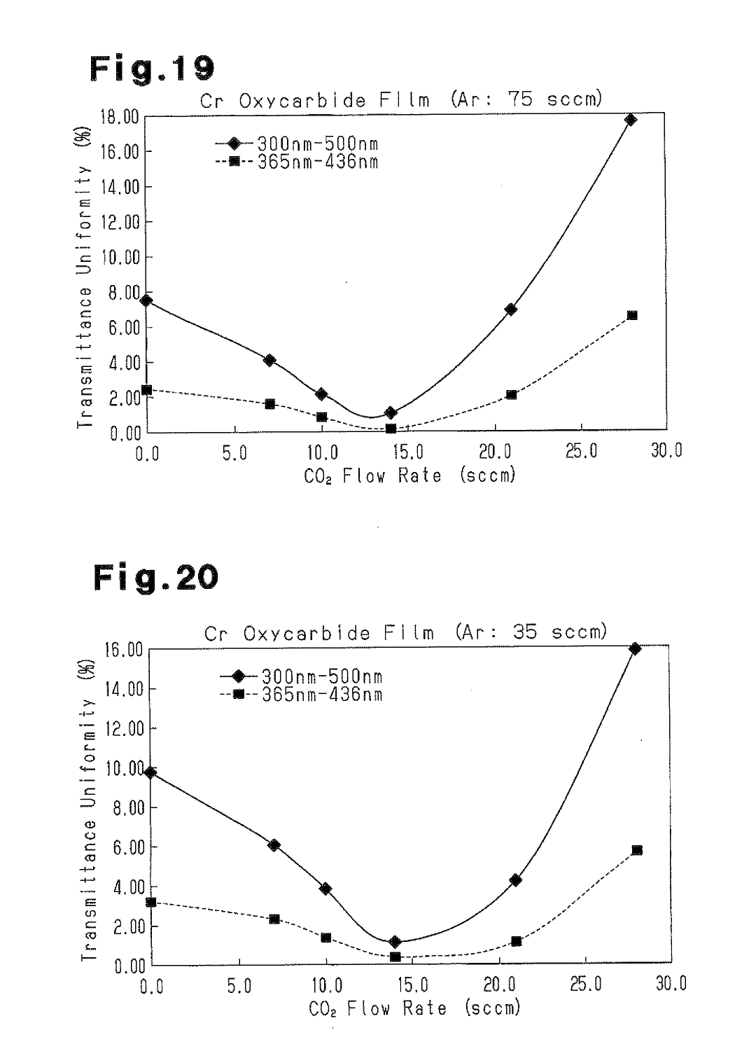

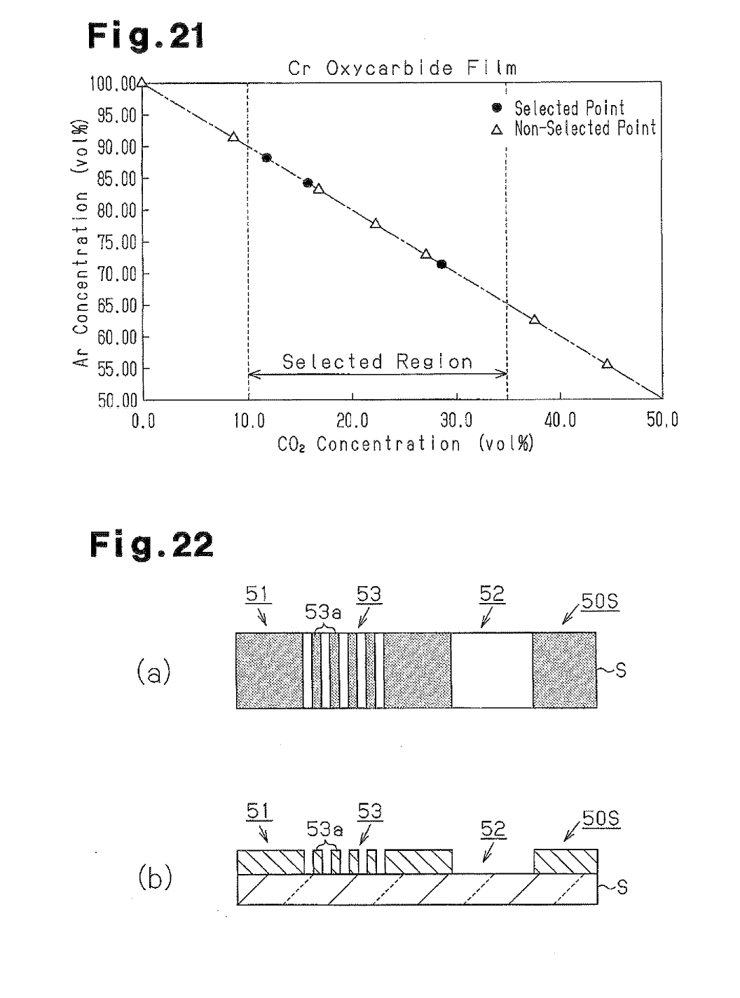

FIG. 8 shows the spectral transmittance curve of a Cr oxycarbide film formed under an Ar flow rate of 75 sccm, the condition of which is included in the above conditions. FIG. 9 shows the spectral transmittance curve of a Cr oxycarbide film formed under an Ar flow rate of 35 sccm, the condition of which is included in the above conditions. Further, FIG. 19 and Table 10 show the transmittance uniformity of the Cr oxycarbide film formed under the condition in which the Ar flow rate is 75 sccm. FIG. 20 and Table 11 show the transmittance uniformity of the Cr oxycarbide film formed under the condition in which the Ar flow rate is 35 sccm. FIG. 21 and Table 12 show a selected region having an N₂ concentration at which the transmittance uniformity in the wavelength range of 365 nm to 436 nm is 1.0% or less or the transmittance uniformity in the wavelength range of 300 nm to 500 nm is 4.0% or less.

As shown in FIG. 8, when the Ar flow rate is 75 sccm, in a film formed under the condition in which the CO₂ flow rate is 0 sccm, as the measured wavelength increases from 300 nm to 500 nm, the transmittance gradually decreases from near 20%. When the CO₂ flow rate gradually increases from 0 sccm, in the transmittance curve of the Cr oxycarbide film, the decreasing gradient of the transmittance becomes gradual. In the Cr oxynitride film formed under the condition that the CO₂ flow rate is 28 sccm, the transmittance gradually increases from near 70%.

The spectral transmittance curve of a film formed under the condition in which the CO₂ flow rate is 0 sccm and the spectral transmittance curve of a Cr oxynitride film formed under the condition that oxynitridation has sufficiently progressed are substantially in line symmetry about a wavelength axis. More specifically, it is apparent that the spectral transmittance curve of a film obtained under the condition in which the CO₂ flow rate is 0 sccm and the spectral transmittance curve of a Cr oxynitride film formed under the condition in which the CO₂ flow rate is 28 sccm are substantially in line symmetry about a wavelength axis extending through a spectral transmittance near 40%. It is also apparent that the transmittance curve of the Cr oxycarbide film at 14 sccm, which is an intermediate value of the two N₂ flow rates that have line symmetrical spectral transmittances, is substantially parallel to a wavelength axis when the wavelength is in the range of 300 nm to 500 nm.

The CO₂ flow rate dependency of the spectral transmittance may also be confirmed from FIG. 9. More specifically, it is apparent that when the Ar flow rate is 35 ccm, the spectral transmittance curve of a Cr film formed under the condition that the CO₂ flow rate is 0 sccm and the spectral transmittance curve of an Cr oxycarbide film formed under the condition in which the CO₂ flow rate is 28 sccm are substantially in line symmetry about a wavelength axis extending through a spectral transmittance near 40%. Further, it is apparent that at 14 sccm, which is the intermediate value of the two CO₂ flow rates that obtain axis symmetrical spectral transmittance, the transmittance curve of the Cr oxycarbide film is substantially parallel to the wavelength axis in the wavelength range of 300 nm to 500 nm.

As shown in FIG. 19, under the condition in which the Ar flow rate is 75 sccm, the transmittance uniformity of the Cr oxycarbide film at 14 sccm, which is the intermediate value, is 0.22% in the wavelength range of 365 nm to 436 nm and 1.03% in the wavelength range of 300 nm to 500 nm. The transmittance uniformity of the Cr oxynitride film decreases as the CO₂ flow rate approaches the intermediate value from 0 sccm. Further, the transmittance uniformity of the Cr oxynitride film in the region including 14 sccm, which is the intermediate value, is 1.0% or less in the range in which the wavelength is 365 nm to 436 nm and 4.0% or less in the range in which the wavelength is 300 nm to 500 nm. Moreover, the transmittance uniformity increases as the CO₂ flow rate increases from the intermediate value. Thus, under the condition in which the Ar flow rate is 75 sccm, in a film formation process for the Cr oxycarbide film, when the intermediate value is set to a target flow rate, which is a target concentration, the transmittance uniformity is further stabilized with respect to the CO₂ flow rate.

The CO₂ flow rate dependency of the transmittance uniformity may also be confirmed from FIG. 20. More specifically, under the condition in which the Ar flow rate is 35 sccm, the transmittance uniformity of the Cr oxycarbide film at 14 sccm, which is the intermediate value, is 0.39% in the wavelength range of 365 nm to 436 nm and 1.09% in the wavelength range of 300 nm to 500 nm. The transmittance uniformity of the Cr oxycarbide film decreases as the CO₂ flow rate approaches the intermediate value from 0 sccm. Further, the transmittance uniformity of the Cr oxycarbide film enters a state in which it is substantially not wavelength dependent in a region including 14 sccm, which is the intermediate value. Furthermore, the transmittance uniformity increases as the CO₂ flow rate increases from the intermediate value. Thus, when the Ar flow rate is 35 ccm, in the film formation process of the Cr oxycarbide film, by using the intermediate value as a target flow rate, which is the target concentration, the transmittance uniformity is further stabilized with respect to the CO₂ flow rate.

In FIG. 21, the volume percentages of the gaseous species obtained from a CO₂ flow rate and an Ar flow rate are respectively referred to as a CO₂ concentration and an Ar concentration. In the above-described film formation conditions, a point at which the transmittance uniformity in the wavelength range of 365 nm to 436 nm is 1.0% or less or the transmittance uniformity in the wavelength range of 300 nm to 500 nm is 4.0% or less is referred to as a selected point. A point at which the transmittance uniformity in the wavelength range of 365 nm to 436 nm is greater than 1.0% and the transmittance uniformity in the wavelength range of 300 nm to 500 nm is greater than 4.0% is referred to as a non-selected point.

As shown in FIG. 21, in a region in which the CO₂ concentration is 10% to 35% and the remnant is formed of Ar, namely, in the region of the selected region of the CO₂ concentration shown in FIG. 21 lying along the single-dashed line, a large number of selected points may be recognized. This is because there is substantially no wavelength dependency at the intermediate value, and such characteristics are easily obtained near the intermediate value. Accordingly, in a film formation process for the Cr oxycarbide film that performs reactive sputtering with a pure Cr target, it is apparent that a Cr oxycarbide film that substantially does not have wavelength dependency is easily obtained by selecting the CO₂ concentration from the region in which the CO₂ concentration is 10% to 35%.

### Example 5

A gray-tone mask for example 5 was formed by using the semi-transparent film (Cr oxynitride film) obtained in example 1. More specifically, a Cr target was used as a target, an Ar gas of 75 sccm was used as a sputtering gas, and an NO gas of 6 sccm was used as a reactive gas to form a semi-transparent film of a Cr oxynitride film on a Cr photomask. Then, a resist pattern was formed on the semi-transparent film. The semi-transparent film and a light shield film (Cr film) were batch-etched to form an open portion. As an etching solution, a Cr etching solution (ceric ammonium nitrate+perchloric acid system) was used.

Subsequently, the resist pattern was removed to form a semi-transparent portion. This obtained the gray-tone mask of example 5. By using the gray-tone mask of example 5, the transmittance of the semi-transparent portion was measured. As a result, due to the semi-transparent portion formed from the chromium oxide film of example 5, the desired transmittance was recognized and the characteristics in which the wavelength dependency of the transmittance is small, that is, the characteristics in which the film is substantially not wavelength dependent was recognized.

### Comparative Example

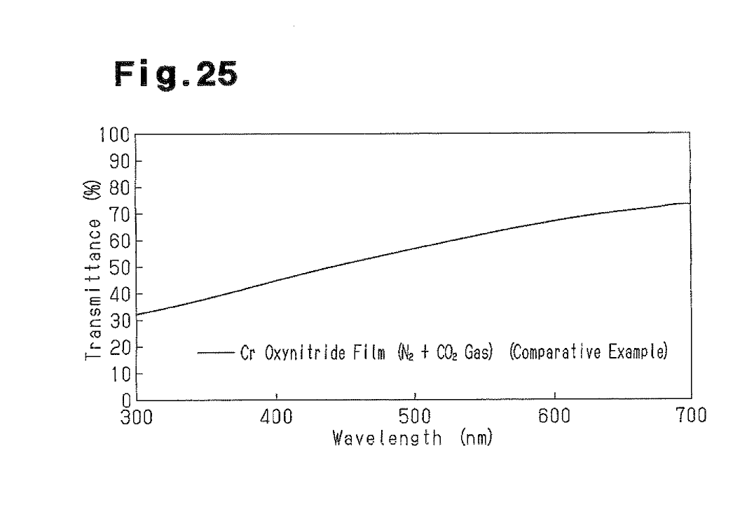

Pure Cr was used as a sputtering target. Further, in the same manner as in example 1, a large interback type film formation apparatus was used. In this case, the film formation temperature, sputtering gas, reactive gas, film formation pressure, and target electric power were under the conditions shown below to obtain a semi-transparent film formed by a Cr oxynitride film of a comparative example. The spectral transmittance for the Cr oxynitride film of the comparative example was measured. The spectral transmittance curve of the comparative example is shown in FIGS. 1 and 25. In this case, the film thickness of the Cr oxynitride film, which was controlled by the conveying speed of the substrate passing through the film formation area to maintain the film quality of the film throughout the substrate, was adjusted to 10 nm to 40 nm, which is the film thickness when the transmittance is 30% to 50%.

Film formation temperature: 150° C. to 200° C.
Sputtering gas/sputtering gas flow rate: Ar/20 sccm
Reactive gas/reactive gas flow rate: carbon dioxide (CO₂)/20 sccm+N₂/35 sccm
Film formation pressure: 2.5×10⁻¹ Pa
Target electric power: approximately 6.0 kW (power density: 2.3 W/cm²)

TABLE 1

| | Added Amount of Nitrogen Monoxide Gas (sccm) | | | | | | |
|---|---|---|---|---|---|---|---|
| | 0.0 | 3.0 | 6.0 | 7.5 | 9.0 | 12.0 | 15.0 |
| Transmittance | 14.02 | 9.85 | 1.08 | 3.00 | 8.79 | 17.66 | 19.18 |
| Uniformity | | | | | | | |
| (300 nm-500 nm) (%) | | | | | | | |
| Transmittance | 4.49 | 3.33 | 0.45 | 0.85 | 2.96 | 5.93 | 6.63 |
| Uniformity | | | | | | | |
| (365 nm-436 nm) (%) | | | | | | | |
| Film Formation | 0.30 | 0.30 | 0.30 | 0.29 | 0.30 | 0.30 | 0.30 |
| Pressure (Pa) | | | | | | | |

TABLE 2

| | Added Amount of Nitrogen Monoxide Gas | | | | | |
|---|---|---|---|---|---|---|
| | (sccm) | | | | | |
| | 0.0 | 4.0 | 6.5 | 8.0 | 10.0 | 13.0 |
| Transmittance Uniformity | 14.16 | 6.75 | 1.10 | 5.03 | 10.15 | 15.90 |
| (300 nm-500 nm) (%) | | | | | | |
| Transmittance Uniformity | 4.70 | 2.49 | 0.31 | 1.72 | 3.40 | 5.63 |
| (365 nm-436 nm) (%) | | | | | | |
| Film Formation | 0.11 | 0.13 | 0.11 | 0.13 | 0.12 | 0.13 |
| Pressure (Pa) | | | | | | |

TABLE 3

| NO vol % | 0.00 | 3.85 | 7.41 | 9.09 | 10.26 | 10.71 |
|---|---|---|---|---|---|---|
| Ar vol % | 100.00 | 96.15 | 92.59 | 90.91 | 89.74 | 89.29 |
| Selected Point | X | X | ◯ | ◯ | X | X |
| NO vol % | 13.79 | 15.66 | 16.67 | 18.60 | 22.22 | 27.08 |
| Ar vol % | 86.21 | 84.34 | 83.33 | 81.40 | 77.78 | 72.92 |
| Selected Point | X | ◯ | X | X | X | X |

TABLE 4

| | Added Amount of Nitrogen Gas (sccm) | | | | | | |
|---|---|---|---|---|---|---|---|
| | 0.0 | 13.0 | 25.0 | 28.0 | 38.0 | 50.0 | 75.0 |
| Transmittance | 9.10 | 4.46 | 1.89 | 1.60 | 1.26 | 3.07 | 5.15 |
| Uniformity | | | | | | | |
| (300 nm-500 nm) (%) | | | | | | | |
| Transmittance | 2.94 | 1.31 | 0.74 | 0.52 | 0.44 | 0.67 | 1.36 |
| Uniformity | | | | | | | |
| (365 nm-436 nm) (%) | | | | | | | |
| Film Formation | 0.30 | 0.33 | 0.38 | 0.37 | 0.41 | 0.45 | 0.57 |
| Pressure (Pa) | | | | | | | |

TABLE 5

| | Added Amount of Nitrogen Gas (sccm) | | | | | |
|---|---|---|---|---|---|---|
| | 0.0 | 13.0 | 20.0 | 25.0 | 38.0 | 50.0 |
| Transmittance Uniformity | 9.30 | 4.46 | 2.62 | 1.15 | 2.65 | 4.01 |
| (300 nm-500 nm) (%) | | | | | | |
| Transmittance Uniformity | 3.23 | 1.21 | 0.85 | 0.50 | 0.56 | 1.19 |
| (365 nm-436 nm) (%) | | | | | | |
| Film Formation | 0.13 | 0.15 | 0.16 | 0.17 | 0.20 | 0.27 |
| Pressure (Pa) | | | | | | |

TABLE 6

| N₂ vol % | 0.00 | 14.77 | 25.00 | 27.08 | 27.18 | 33.63 |
|---|---|---|---|---|---|---|
| Ar vol % | 100.00 | 85.23 | 75.00 | 72.92 | 72.82 | 66.37 |
| Selected Point | X | X | ◯ | X | ◯ | ◯ |
| N₂ vol % | 36.36 | 40.00 | 44.44 | 50.00 | 52.05 | 58.82 |
| Ar vol % | 63.64 | 60.00 | 55.56 | 50.00 | 47.95 | 41.18 |
| Selected Point | ◯ | ◯ | ◯ | X | ◯ | X |

TABLE 7

| | Added Amount of Nitrogen Gas (sccm) | | | | | |
|---|---|---|---|---|---|---|
| | 0.0 | 15.0 | 30.0 | 45.0 | 60.0 | 90.0 |
| Transmittance Uniformity | 3.70 | 3.03 | 0.65 | 1.61 | 3.06 | 4.43 |
| (300 nm-500 nm) (%) | | | | | | |
| Transmittance Uniformity | 1.38 | 0.58 | 0.50 | 0.64 | 1.27 | 1.99 |
| (365 nm-436 nm) (%) | | | | | | |
| Film Formation | 0.44 | 0.47 | 0.51 | 0.54 | 0.58 | 0.64 |
| Pressure (Pa) | | | | | | |

TABLE 8

| | Added Amount of Nitrogen Gas (sccm) | | | | | |
|---|---|---|---|---|---|---|
| | 0.0 | 10.0 | 20.0 | 30.0 | 40.0 | 60.0 |
| Transmittance Uniformity | 4.07 | 2.12 | 0.88 | 1.77 | 3.21 | 4.65 |
| (300 nm-500 nm) (%) | | | | | | |
| Transmittance Uniformity | 2.03 | 0.91 | 0.39 | 0.53 | 1.08 | 1.52 |
| (365 nm-436 nm) (%) | | | | | | |
| Film Formation | 0.22 | 0.25 | 0.29 | 0.31 | 0.34 | 0.40 |
| Pressure (Pa) | | | | | | |

TABLE 9

| | | | | | | |
|---|---|---|---|---|---|---|
| N₂ vol % | 0.00 | 16.67 | 22.22 | 28.57 | 37.50 | 44.44 |
| Ar vol % | 100.00 | 83.33 | 77.78 | 71.43 | 62.50 | 55.56 |
| Selected | X | ◯ | ◯ | ◯ | ◯ | X |
| Point | | | | | | |

| | | | | | |
|---|---|---|---|---|---|
| N₂ vol % | 46.15 | 54.55 | 56.25 | 63.16 | 72.00 |
| Ar vol % | 53.85 | 45.45 | 43.75 | 36.84 | 28.00 |
| Selected | ◯ | X | ◯ | X | X |
| Point | | | | | |

TABLE 10

| | Added Amount of CO₂ Gas (sccm) | | | | | |
|---|---|---|---|---|---|---|
| | 0.0 | 7.0 | 10.0 | 14.0 | 21.0 | 28.0 |
| Transmittance Uniformity | 7.48 | 4.11 | 2.19 | 1.03 | 6.95 | 17.53 |
| (300 nm-500 nm) (%) | | | | | | |
| Transmittance Uniformity | 2.47 | 1.59 | 0.88 | 0.22 | 2.09 | 6.49 |
| (365 nm-436 nm) (%) | | | | | | |
| Film Formation | 0.58 | 0.58 | 0.59 | 0.59 | 0.59 | 0.60 |
| Pressure (Pa) | | | | | | |

TABLE 11

| | Added Amount of CO₂ Gas (sccm) | | | | | |
|---|---|---|---|---|---|---|
| | 0.0 | 7.0 | 10.0 | 14.0 | 21.0 | 28.0 |
| Transmittance Uniformity | 9.79 | 6.10 | 3.75 | 1.09 | 4.30 | 15.81 |
| (300 nm-500 nm) (%) | | | | | | |
| Transmittance Uniformity | 3.22 | 2.30 | 1.41 | 0.39 | 1.14 | 5.70 |
| (365 nm-436 nm) (%) | | | | | | |
| Film Formation | 0.27 | 0.27 | 0.27 | 0.27 | 0.29 | 0.33 |
| Pressure (Pa) | | | | | | |

TABLE 12

| | | | | | | |
|---|---|---|---|---|---|---|
| CO₂ vol % | 0.00 | 8.54 | 11.76 | 15.73 | 16.67 | 21.88 |
| Ar vol % | 100.00 | 91.46 | 88.24 | 84.27 | 83.33 | 78.12 |
| Selected Point | X | X | ◯ | ◯ | X | X |

| | | | | | |
|---|---|---|---|---|---|
| CO₂ vol % | 22.22 | 27.18 | 28.57 | 37.50 | 44.44 |
| Ar vol % | 77.78 | 72.82 | 71.43 | 62.50 | 55.56 |
| Selected Point | X | X | ◯ | X | X |

The method for manufacturing a gray-tone mask according to the embodiment has the advantages described below.

(1) In the embodiment described above, by using a reactive sputtering method that sputters a pure Cr target in an atmosphere of Ar and NO, a Cr oxynitride film having a single-layer structure is formed as a semi-transparent film. At this case, based on a plurality of different spectral transmittance curves obtained from a plurality of film formation conditions having different NO concentrations, a target concentration (intermediate value) of NO is obtained at which the transmittance uniformity of the semi-transparent film is 1.0% or less in the wavelength range of 365 nm to 436 nm or 4.0% or less in the wavelength range of 300 nm to 500 nm. Then, by using NO of the target concentration, a semi-transparent film is formed.

Accordingly, in the embodiment described above, based on the plurality of different spectral transmittance curves obtained at different NO concentrations, the target concentration for obtaining a semi-transparent film which is substantially not wavelength dependent is obtained. As a result, in the embodiment described above, just by adjusting the NO concentration, a single-layer structure semi-transparent film that is substantially not wavelength dependent is obtained. Therefore, the method for manufacturing a gray-tone mask decreases the wavelength dependency with respect to the exposure wavelength of the gray-tone mask under stable and easy film formation conditions.

(2) In the embodiment described above, by using a reactive sputtering method which sputters a pure Cr target in an atmosphere of Ar and N₂, a single-layer structure Cr nitride film is formed as a semi-transparent film. In this case, based on the plurality of different spectral transmittance curves obtained from a plurality of film formation conditions having different N₂ concentrations, a target concentration (intermediate value) of N₂ at which the transmittance uniformity of the semi-transparent film is 1.0% or less in the wavelength range of 365 nm to 436 nm or 4.0% or less in the wavelength range of 300 nm to 500 nm is obtained. Then, the N₂ target concentration is used to form a semi-transparent film.

Further, by using a reactive sputtering method that sputters an NiCr target in an atmosphere of Ar and N₂, a single-layer structure Cr nitride film is formed as a semi-transparent film. In this case, based on a plurality of different spectral transmittance curves obtained under a plurality of film formation conditions having different N₂ concentrations, an N₂ target concentration (intermediate value) is obtained so that the transmittance uniformity of the semi-transparent film is 1.0% or less in the wavelength range of 365 nm to 436 nm or 4.0% or less in the wavelength range of 300 nm to 500 nm. Then, by using the N₂ target concentration, a semi-transparent film is formed.

Accordingly, in these embodiments, just by adjusting the N₂ concentration, a single-layer structure semi-transparent film that is substantially not wavelength dependent is obtained.

(3) In the embodiment described above, by using a reactive sputtering method for sputtering a pure Cr target in an atmosphere of Ar and CO₂, a chromium oxycarbide film having a single-layer structure is formed as a semi-transparent film. In this case, based on a plurality of different spectral transmittance curves obtained from a plurality of film formation conditions having different CO₂ concentrations, an NO target concentration (intermediate value) at which the transmittance uniformity of the semi-transparent film is 1.0% or less in the wavelength range of 365 nm to 436 nm or 4.0% or less in the wavelength range of 300 nm to 500 nm is obtained. Then, by using the CO₂ target concentration, a semi-transparent film is formed.

Accordingly, in the embodiment described above, based on the plurality of different spectral transmittance curves obtained under the plurality of film formation conditions having different CO₂ concentrations, the target concentration for obtaining a semi-transparent film that is substantially not wavelength dependent is obtained. As a result, in the embodiment described above, just by adjusting the CO₂ concentration, a single-layer structure semi-transparent film that is substantially not wavelength dependent is obtained. Thus, the method for manufacturing a gray-tone mask in the embodiment described above decreases the wavelength dependency with respect to the exposure wavelength of the gray-tone mask under stable and easy film formation conditions.

The above embodiment may be modified as described below.

In the embodiment described above, the examples use NO, N₂, or CO₂ as reactive gas. However, the embodiment described above is not limited to the foregoing description, and the method may use at least one selected from the group consisting of oxygen, carbon monoxide, carbon dioxide, nitrogen monoxide, nitrogen dioxide, nitrogen, and methane. In such a manufacturing method, the same effect as that in the embodiment described above may be obtained.

In the embodiment described above, an example uses an alloy target 92 atomic percent of Ni and 8 atomic percent of Cr as an Ni alloy target. However, the embodiment described above is not limited to the foregoing description, and a target formed from an alloy of Ni and a metal-containing element, in which the metal-containing element is at least one selected from the group consisting of Ti, Zr, Hf, V, Nb, Ta, W, Cu, Fe, Al, Si, Cr, Mo, and Pd, at a total of 5 atomic percent to 40 atomic percent may be used. Even in such a manufacturing method, the same advantages as that of example 3 are obtained.

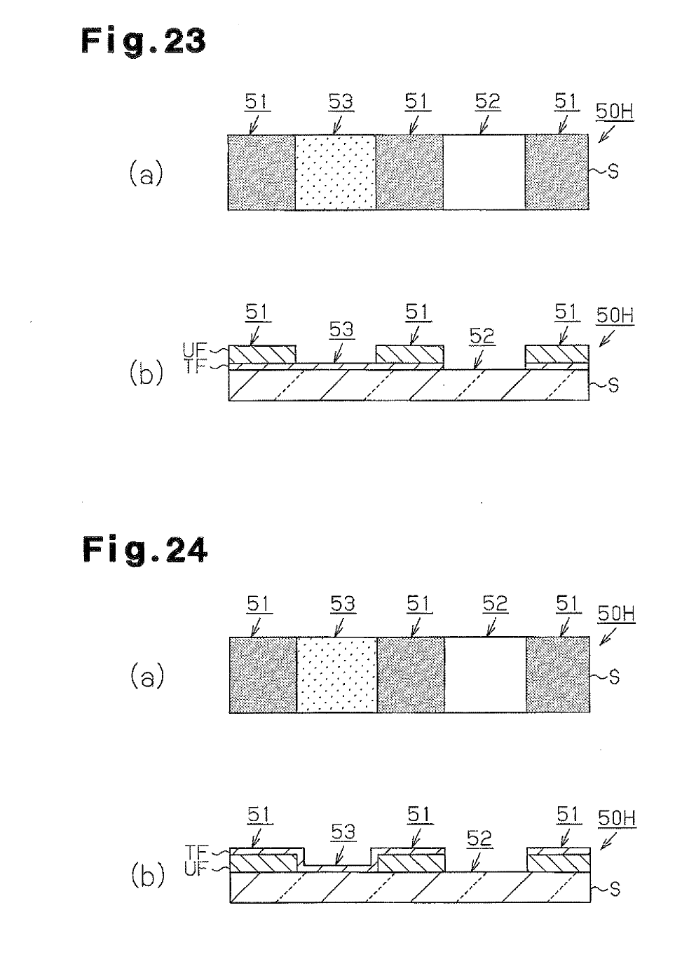

In the above embodiment, examples in which a semi-transparent film is formed on a Cr photomask as a method for manufacturing a gray-tone mask are discussed. However, the embodiment described above is not limited to the foregoing description, and as a method for manufacturing a gray-tone mask, a semi-transparent film may be formed on a transparent substrate S, and a light shield film may then be formed on the semi-transparent film to obtain a gray-tone mask shown in FIG. 23. Further, as the method for manufacturing a gray-tone mask, a semi-transparent film may be formed on the transparent substrate S. Then, an etching stopper film may be formed on the semi-transparent film, and a light shield film may be formed on the etching stopper film. In such a manufacturing method, the same advantages as that of example 5 are obtained.

In the embodiment described above, the examples in which the transmittance of a semi-transparent film is 30% to 500 are discussed. However, the embodiment described above is not limited to the foregoing description, and the transmittance of a semi-transparent film may be selected from the range of 5% to 80% in accordance with various conditions required for the fabrication of a flat panel display.

1. A method for manufacturing a gray-tone mask including a semi-transparent film, the method comprising the step of:
forming the semi-transparent film with a single-layer structure by using a reactive sputtering method that sputters a target formed from a Cr or Ni alloy in an atmosphere of a reactive gas and a sputtering gas, wherein the reactive gas contains at least one selected from the group consisting of oxygen, carbon monoxide, carbon dioxide, nitrogen monoxide, nitrogen dioxide, nitrogen, and methane, and the step of forming the semi-transparent film includes:
acquiring spectral transmittance curves of a plurality of thin films under a plurality of film formation conditions having different concentrations of the reactive gas;
acquiring from the spectral transmittance curves of the plurality of thin films a target concentration for the reactive gas that is a concentration at which the difference between a maximum value and a minimum value of a transmittance of the semi-transparent film is 1.0% or less in the wavelength range of 365 nm to 436 nm or 4.0% or less in the wavelength range of 300 nm to 500 nm; and
forming the semi-transparent film by using the reactive gas of the target concentration.

2. The method for manufacturing a gray-tone mask according to claim 1, wherein:
the target is a Cr target;
the reactive gas is nitrogen monoxide;
the target concentration is a concentration selected from 6 vol % to 16 vol %; and
the sputtering gas is argon.

3. The method for manufacturing a gray-tone mask according to claim 1, wherein:
the target is a Cr target;
the reactive gas is carbon dioxide;
the target concentration is a concentration selected from 10 vol % to 35 vol %; and
the sputtering gas is argon.

4. The method for manufacturing a gray-tone mask according to claim 1, wherein:
the target is a Cr target;
the reactive gas is nitrogen;
the target concentration is a concentration selected from 20 vol % to 55 vol %; and
the sputtering gas is argon.

5. The method for manufacturing a gray-tone mask according to claim 1, wherein:
the target is an alloy target formed from 92 atomic percent of Ni and 8 atomic percent of Cr;
the reactive gas is nitrogen;
the target concentration is a concentration selected from 10 vol % to 60 vol %; and
the sputtering gas is argon.

6. The method for manufacturing a gray-tone mask according to claim 1, wherein:
the Ni alloy is an alloy of Ni and a metal-containing element; and
the metal-containing element contains at least one selected from the group consisting of Ti, Zr, Hf, V, Nb, Ta, W, Cu, Fe, Al, Si, Cr, Mo, and Pd at a total of 5 to 40 atomic percent.

7. The method for manufacturing a gray-tone mask according to claim 1, wherein the step of forming the semi-transparent film includes forming the semi-transparent film on a transparent substrate, the method further comprising the step of:
forming a light shield film on the semi-transparent film.

8. The method for manufacturing a gray-tone mask according to claim 1, further comprising the step of:
forming a light shield film on a transparent substrate, wherein the step of forming the semi-transparent film includes:
arranging an open portion from which the transparent substrate is exposed in the light shield film; and
forming the semi-transparent film on the exposed transparent substrate.

9. The method for manufacturing a gray-tone mask according to claim 1, wherein the step of forming the semi-transparent film includes forming the semi-transparent film on a transparent substrate, the method further comprising the steps of:
forming an etching stopper film on the semi-transparent film; and
forming a light shield film on the etching stopper film.

10. The method for manufacturing a gray-tone mask according to claim 2, wherein the step of forming the semi-transparent film includes forming the semi-transparent film on a transparent substrate, the method further comprising the step of:
forming a light shield film on the semi-transparent film.

11. The method for manufacturing a gray-tone mask according to claim 2, further comprising the step of:
forming a light shield film on a transparent substrate, wherein the step of forming the semi-transparent film includes:
arranging an open portion from which the transparent substrate is exposed in the light shield film; and
forming the semi-transparent film on the exposed transparent substrate.

12. The method for manufacturing a gray-tone mask according to claim 2, wherein the step of forming the semi-transparent film includes forming the semi-transparent film on a transparent substrate, the method further comprising the steps of:
forming an etching stopper film on the semi-transparent film; and
forming a light shield film on the etching stopper film.

13. The method for manufacturing a gray-tone mask according to claim 3, wherein the step of forming the semi-transparent film includes forming the semi-transparent film on a transparent substrate, the method further comprising the step of:
forming a light shield film on the semi-transparent film.

14. The method for manufacturing a gray-tone mask according to claim 3, further comprising the step of:
forming a light shield film on a transparent substrate, wherein the step of forming the semi-transparent film includes:
arranging an open portion from which the transparent substrate is exposed in the light shield film; and
forming the semi-transparent film on the exposed transparent substrate.

15. The method for manufacturing a gray-tone mask according to claim 3, wherein the step of forming the semi-transparent film includes forming the semi-transparent film on a transparent substrate, the method further comprising the steps of:
forming an etching stopper film on the semi-transparent film; and
forming a light shield film on the etching stopper film.

16. The method for manufacturing a gray-tone mask according to claim 4, wherein the step of forming the semi-transparent film includes forming the semi-transparent film on a transparent substrate, the method further comprising the step of:
forming a light shield film on the semi-transparent film.

17. The method for manufacturing a gray-tone mask according to claim 4, further comprising the step of:
forming a light shield film on a transparent substrate, wherein the step of forming the semi-transparent film includes:
arranging an open portion from which the transparent substrate is exposed in the light shield film; and
forming the semi-transparent film on the exposed transparent substrate.

18. The method for manufacturing a gray-tone mask according to claim 4, wherein the step of forming the semi-transparent film includes forming the semi-transparent film on a transparent substrate, the method further comprising the steps of:
forming an etching stopper film on the semi-transparent film; and
forming a light shield film on the etching stopper film.

19. The method for manufacturing a gray-tone mask according to claim 5, wherein the step of forming the semi-transparent film includes forming the semi-transparent film on a transparent substrate, the method further comprising the step of:
forming a light shield film on the semi-transparent film.

20. The method for manufacturing a gray-tone mask according to claim 5, further comprising the step of:
forming a light shield film on a transparent substrate, wherein the step of forming the semi-transparent film includes:
arranging an open portion from which the transparent substrate is exposed in the light shield film; and
forming the semi-transparent film on the exposed transparent substrate.
